(19) United States
(12) Patent Application Publication
(10) Pub. No.: US 2022/0377945 A1
(43) Pub. Date: Nov. 24, 2022

(54) Heat Sink

(71) Applicant: Aptiv Technologies Limited, St. Michael (BB)

(72) Inventors: Falk Rademacher, Gummersbach (DE); Peter Reinhold, Gummersbach (DE); Alf Bretschneider, Engelskirchen-Ründeroth (DE)

(21) Appl. No.: 17/663,988

(22) Filed: May 18, 2022

(30) Foreign Application Priority Data
May 20, 2021 (EP) 21174873.6

(51) Int. Cl. H05K 7/20; H01L 23/40

(52) U.S. Cl. CPC H05K 7/20854; H05K 7/20409; H01L 23/40; H05K 7/205

(57) ABSTRACT

A heat sink comprising a body non-adjustably mountable on a support provided with at least one element to be cooled, characterized in that said body comprises at least one insert that is adjustably fitted therein so that an insert contact surface comes into contact with the element to be cooled.

### CROSS-REFERENCE TO RELATED APPLICATION

This application claims priority to European Patent Application Number 21174873.6, filed May 20, 2021, the disclosure of which is incorporated by reference in its entirety herein.

### BACKGROUND

Many electronic components such as integrated circuits (IC) with high power dissipation generate thermal energy. In many cases, heat generated by an integrated circuit should be transferred to an ambient environment to maintain a junction temperature of the component within safe operating limits. If thermal energy is not transferred away from the integrated circuit, it can cause defects to a host and the integrated circuit may be damaged, destroyed, or shut down.

To prevent such issues, heat sinks are often connected to integrated circuits to transfer thermal energy. For example, thermal energy may be transferred to a movable medium, such as a gaseous medium like air or another medium like water or oil. These mediums can transfer the thermal energy to colder areas where the heat can be exchanged out of the electronic circuits and, thereby, cool the device.

Typically, a heat sink arranged onto a printed circuit board is provided with a body having columns acting as legs for securing the heat sink to the printed circuit board, especially at least over the heating source of the board which is generally constituted by one or more processors, chips, or chipsets. Located at the back of the surface facing the printed circuit board, the body may be provided with a plurality of protruding elements that play the role of heat exchangers. Instead or in addition, the body may also be provided with cooling channels in order to help extract heat from the heating source.

For heat transfer efficiency reasons, the body of the heat sink further includes pads, blocks, or contact members disposed near in proximity (e.g., as near as possible to maximize efficiency) to the heat source. However, due to several reasons, pads may not properly reach the upper surface of each chip or integrated circuit to be cooled. The aforementioned reasons mainly result from assembly tolerances between the heat sink and the printed circuit board. In addition, the package surface of the integrated circuit sometimes has planarity deficiencies that give the surface concave, convex, or even twisted shapes. For any of these reasons, there may often be a gap between the upper package surface of the integrated circuits and the lower contact surfaces or pads of the heat sink. Since air essentially functions as a thermal insulator, it is desirable to eliminate any interstitial air gap since it may act as a significant resistance to heat flow.

To efficiently remove heat from the heating source, there is a need to fill each gap using a gap filler also referred to as thermal interface material (TIM). A large variety of material types having a greater thermal conductivity than the air have been developed as thermal interface materials.

From the foregoing, one can note that the thermal efficiency of a heat sink is strongly dependent on the gap between the upper package surface of the integrated circuit and the lower surface of the heat sink pad that is intended to come into contact with the heating element. Indeed, generally, the smaller the gap, the higher the thermal efficiency.

Known heat sinks in automotive industry, especially in vehicle (e.g., automobile) electronic control units (ECUs), are generally integrated in the enclosure of the ECU. Such heat sinks further are configured to fixedly hold the printed circuit board of the ECU. Accordingly, their function may double. Specifically, they may both cool the heating element(s) of the printed circuit board and secure the latter within the ECU enclosure. However, the designs of such heat sinks often do not provide optimum heat dissipation, mainly due to the tolerance stack at the gap which is filled by the thermal interface material.

In other technical field, some heat sinks use compression spring connection means located at the four corners of the heat sink body for securing the latter to the printed circuit board. Such a design allows to adjust the distance between the base of the body and the upper package surface of the integrated circuit of the board. However, to obtain a correct adjustment, it is necessary to adjust the four screws that are provided with the connection means and allow to compress or release the helical springs of the connections. Such an adjustment is quite long to implement, especially due to the fact that it is particularly difficult to make the base of the heat sink parallel to the upper package surface of the integrated circuit. In addition, such a design does not allow an integration into an ECU enclosure provided with a liquid or air cooling channel due to the movability of the body. Furthermore, the connection means are likely to go out of adjustment, especially when the printed circuit board or the ECU enclosure is subject to vibrations or shocks, which is the case in certain fields, in particular in the automotive industry. Further, the aforementioned design is not suitable when the printed circuit board is provided with several heating elements having different heights protruding above the upper plane of the printed circuit board. Indeed, in such a case, only the highest heating element may come into contact with the base of the heat sink in an optimal way.

### SUMMARY

The present disclosure provides a heat sink comprising a body non-adjustably mountable on a support provided with at least one element to be cooled. The body comprises at least one insert that is adjustably fitted therein, so that an insert contact surface comes into contact with the element to be cooled.

Due to the features of the above heat sink, the insert can be adjusted, with respect to the immovable body attached to the support, in such a way as to come in contact or almost contact with the element to be cooled. Accordingly, any gap resulting from mounting tolerances between the heat sink and the support on which it is attached can be compensated for by the adjustment function of the insert in relation to the body of the heat sink. As a result, the present heat sink provides an optimum dissipation of the heat generated by the heating element(s) of the support to be cooled regardless of certain dimensional flaws that may typically result from machining, mounting and/or assembly tolerances.

In addition, since the body of the heat sink of the present disclosure remains immovable relative to the support or printed circuit board on which it is secured, it is fully designed to be integrated into an enclosure, such as an ECU housing, which may further be provided with a liquid or air cooling channel.

In some implementations, the present heat sink is adjustable along an axis of movement that is orthogonal to an element contact surface of the element to be cooled. In an implementation, the insert is adjustably fitted into the body by means of a first threaded part of the insert which engages a second threaded part of the body. The first threaded part may be located at a periphery of the insert and the second threaded part may be a threaded hole arranged within the body.

According to one implementation, the insert is adjustably fitted into the body by means of a push-fit inter-engagement. The inter-engagement between the body and the insert may involve a periphery of the insert in its entirety.

In one implementation, the heat sink further comprises a sealing between the insert and the body. Depending on the implementation, the sealing may be a thread sealant or a thread lock. In one implementation, the sealing is an O-ring which protrudes at a periphery of the insert. In a further implementation, the insert is adjustably fitted into the body for coming into contact with the element to be cooled via a first layer of a thermal interface material. The insert may further comprise a gripping means for helping the insert to be adjusted within the body. In an additional implementation, the insert further comprises a plurality of heat exchanger elements arranged on a free surface opposite to the insert contact surface.

The body further may further comprise, on a body free surface opposite to the element to be cooled, at least one of a plurality of heat exchanger elements and at least one cooling channel for transporting a fluid. In addition, the present disclosure further relates to a printed circuit board as a support non-adjustably mounted on a heat sink according to any of its implementations or according to any possible combination of its implementations. The present disclosure also relates to a vehicle comprising the aforementioned printed circuit board. Additional implementations may be disclosed hereafter in the detailed description.

### BRIEF DESCRIPTION OF THE DRAWINGS

The disclosure and the implementations provided in the present description should be taken as non-limitative examples and may be better understood with reference to the attached figures in which:

FIG. 1 illustrates a perspective representation of one implementation of the heat sink of the present disclosure mounted on a support and depicted according to a partial vertical section;

FIG. 2 illustrates an elevation view of another implementation of the heat sink of the present disclosure in which only the body has been depicted in vertical section;

FIG. 3 illustrates a first variant of the implementation shown in FIG. 1;

FIG. 4 illustrates a second variant of the implementation shown in FIG. 1; and

FIG. 5 illustrates another implementation of the present heat sink.

### DETAILED DESCRIPTION

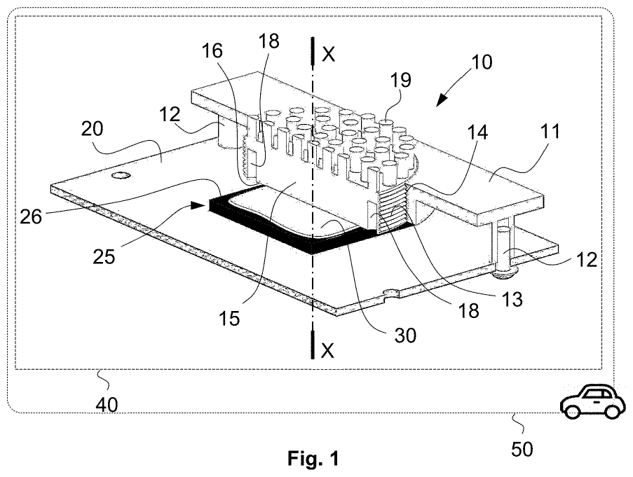

FIG. 1 illustrates a perspective representation of one implementation of the heat sink of the present disclosure mounted on a support and depicted according to a partial vertical section. As illustrated, a heat sink 10, such as a heat dissipater or a heat spreader, is mounted on a support 20 provided with an element 25 to be cooled. The element 25 to be cooled may also be regarded as a heating element 25 which is immovable with respect to its support 20. The element 25 to be cooled may typically be a chip, a chipset, an integrated circuit (IC), a central processing unit (CPU) or any other semiconductor. It should be noted that the element 25 to be cooled is not limited to an electronic component but may also be an electrical element such as a transformer. The support 20 may be a plate or any element to be assembled to the heat sink 10. In some implementations, the support 20 is a printed circuit board (PCB). It may relate to a PCB of an electronic control unit (ECU) (e.g., a PCB belonging to a vehicle's ECU for instance).

Depending on the relative sizes of the heat sink 10 and the support 20, the heat sink 10, in one implementation, is supported by the support 20 (e.g., if the support 20 is larger than the heat sink 10). In a second implementation, the support 20 is supported by the heat sink 10 (e.g., in the case where the support 20 is smaller than the heat sink 10). The two aforementioned implementations should be considered as equivalent in the present disclosure given that the main role of the support 20 is to be assembled to the heat sink 10 in order to cool the heating element(s) 25 that the support 20 includes. The aforementioned support may also be considered to have been so named in reference to the at least one element 25 to be cooled that it carries.

The illustration of FIG. 1, as well as those in the other figures, is a schematic representation in which the PCB, namely the carrier or support 20, and its IC have been simplified for clarity purposes. To better show the assembly, FIG. 1 has been provided in a perspective view in which the heat sink 10 is shown in a partial vertical cross section.

The implementation depicted in FIG. 1 further shows a thermal interface material 30 that has been arranged on the upper package surface of the element 25 to be cooled. The upper package surface of the element 25 may be also referred to as the element contact surface 26 in the present disclosure. The thermal interface material 30 is fully optional and can be used, for example, to compensate certain flatness defaults of the element contact surface 26 or a possible lack of parallelism between the heat sink 10 and the element contact surface 26.

As shown in FIG. 1, the heat sink 10 includes a body 11 that is mountable on the support 20. More specifically, the body 11 is non-adjustably mounted on the support 20. To this end, it may have several legs 12 that allow to secure it to the support 20, for example, using fastening screws 22 that connect the body 11 to the support 20 through the legs 12 which are each provided with a treaded hole. Other attachment means such as rivets or interlocking means can be used.

According to the present disclosure, the body 11 has at least one insert 15, or spread insert, that is adjustably fitted to the body 11 so that an insert contact surface 16 can come into contact with the element 25 to be cooled. Therefore, the insert 15 is adjustable within the body 11, relative to the latter. Since the body 11 is fixedly mounted on the support 20, it also means that the insert 15 is adjustable relative to the support 20. For example, the insert 15 is adjustable along an axis of movement X-X that is perpendicular to the element contact surface 26 of the element 25 to be cooled.

Due to the features of the present heat sink 10, it becomes possible to adjust the insert 15, so that at least a part of the heat sink 10 can be moved against or as close as possible towards the element contact surface 26 of the element 25 to be cooled. Such a design allows to ensure the smallest gap, or even no gap, between the element 25 to be cooled and the heat sink 10. Accordingly, the thermal efficiency of the heat sink 10 can be increased.

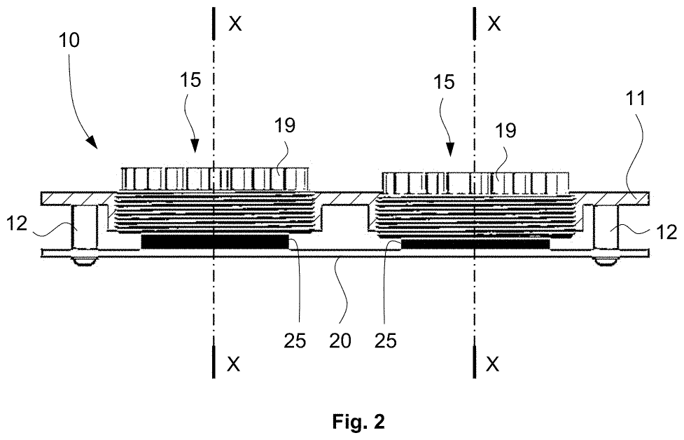

Furthermore, the present heat sink 10 is not limited to have a single insert 15 but may include several inserts 15 which can be each adjusted independently from the others, as depicted in the example of FIG. 2. FIG. 2 illustrates an elevation view of another implementation of the heat sink 10 of the present disclosure in which only the body 11 has been depicted in vertical section.

If the same support 20 has several elements 25 to be cooled which have elements contact surfaces protruding at different heights above the support 20, the present heat sink 10 has the ability to adapt to each of the elements 25 of the support 20. For example, the heat sink 10 of the present disclosure is particularly efficient, not only with a support 20 comprising a single element 25 to be cooled, but also with a support 20 comprising a plurality of elements 25, even if those or a part of them protrude at different levels above the support 20, as shown in FIG. 2.

Moreover, the present heat sink 10 may not include an elastic member for connecting the body 11 to the support 20, so that no relative movement can be observed between them. Accordingly, the heat sink 10 may be convenient for integration into an enclosure, such as a housing for an ECU which may be provided with a fluid (liquid or gas) cooling channel. Further, the rigid attachment of the present heat sink 10 to its support 20 may beneficially provide a monolithic element that is non sensitive to vibrations. Consequently, the heat sink 10 is particularly well-designed for mounting on a vehicle or any device subject to movements or vibrations.

Although the insert 15 may be adjustable along an axis of movement X-X that is orthogonal to the support 20 (e.g., perpendicular to the element contact surface 26 of the element 25 of the support 20) it should be noted that the insert 15 can also be adjustable according to a slanted axis of movement, for example, using inclined sliding grooves arranged within the body 11. In such a case, the insert 15 may be provided with protrusions intended to engage the grooves of the body 11. A dovetail profile assembly (e.g., inclined at an acute angle relative to the planar surface of the support 20) may be used for example to move the insert 15 into the body 11, until the insert 15 comes into contact with the element 25 to be cooled or comes close to the element 25. In such an implementation, it should be noted that the insert 15 may have a shape which is not circular, when seen from above (e.g., in a direction according to the axis X-X of FIG. 1). Such a shape may be a square or rectangular shape for instance.

In an example of an implementation, the heat sink 10 is adjustably fitted into the body 11 by means of a first threaded part 13 of the insert 15 which engages a second threaded part 14 of the body 11. As illustrated in the implementations of FIGS. 1, 2, 4 and 5, the first threaded part 13 is located at the periphery of the insert 15 and the second threaded part 14 is a threaded hole arranged within the body 11. In such a case, the periphery of the insert 15 presents a substantially circular shape and the insert 15 may have a generally cylindrical outer shape.

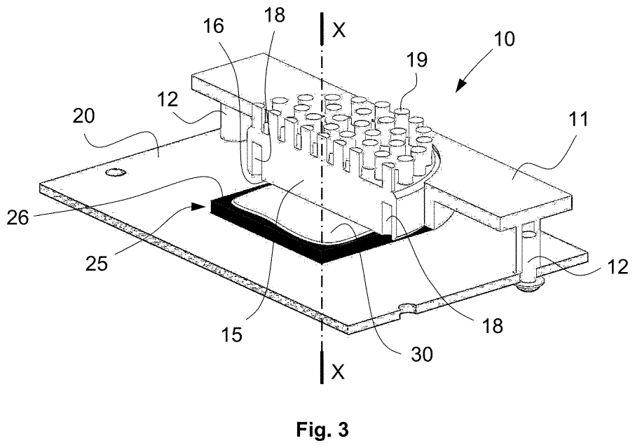

FIG. 3 illustrates a first variant of the implementation shown in FIG. 1. As illustrated, the insert 15 is adjustably fitted into the body 11 via a push-fit inter-engagement. To this end, there may not be a threaded part at either the outer periphery of the insert 15 or at the inner surface of the hole or opening intended to host the insert 15, but both the outer periphery of the insert 15 and the aforementioned inner surface are sized to allow a push-fit inter-engagement, namely a press-fit connection in which there may be no play between the insert 15 and the body 11.

In additional implementations, also depicted in FIG. 3, the inter-engagement between the body 11 and the insert 15 involves the periphery of the insert 15 in its entirety. Such an implementation ensures good heat transfer between the insert 15 and the body 11, thus allowing an efficient cooling of the element 25 to be cooled.

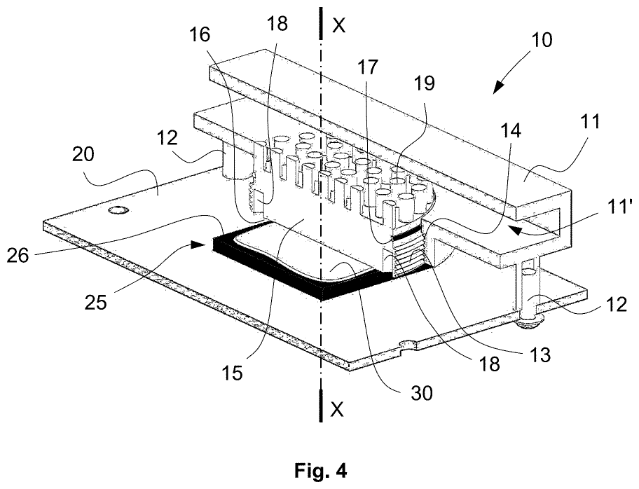

According to another implementation, the heat sink 10 further includes a sealing 17 between the insert 15 and the body 11. Such a sealing 17 is shown in the implementation depicted in FIG. 3 which is similar to that of FIG. 1 in the sense that it includes the aforementioned first and second threaded parts 13, 14. In some implementations, the sealing 17 is part of the insert 15, as shown in FIG. 4.

FIG. 4 illustrates a second variant of the implementation shown in FIG. 1. As illustrated, the sealing 17 is located above the first threaded part 13, namely at a location that is more distant from the insert contact surface 16 than the latter is from the first threaded part 13. In an alternative implementation, the sealing 17 may be arranged in the body 11 (e.g., within the inner surface of the hole or opening arranged in the body 11 for receiving the insert 15, especially if the latter is adjustably fitted into the body 11 by means of a push-fit inter-engagement).

In one implementation, the sealing 17 is a threaded sealant or a thread lock. Of course, such a sealing 17 is intended to be provided with one of the implementations in which the insert 15 is adjustably fitted into the body 11 by means of the first and second threaded parts 13, 14.

According to another implementation, the sealing 17 is an O-ring. In some implementations, such an O-ring is intended to protrude at the periphery of the insert 15, as depicted in the example of FIG. 4. Whatever its implementation, the sealing 17 may also prevent any accidental displacement of the insert 15 within the body 11 which may result from vibrations for example. Besides, the sealing 17 may be also used to meet ingress protection class requirements, especially against the ingress of dust and/or liquid, including cooling liquid that may be used in a cooling channel 11′, as schematically depicted in the example of FIG. 4. In further implementations, a glue connection may be arranged between the insert 15 and the body 11, instead of the sealing 17 or in addition to the latter. Such a glue connection may also fixedly position the insert 15 within the body 11, once the insert 15 has been properly adjusted with respect to the contact surface 26 of the element 25 to be cooled.

In a further implementation, the insert 15 is adjustably fitted into the body for coming into contact with the element 25 to be cooled via a first layer of a thermal interface material 30, as shown in the attached figures. The thermal interface material may be regarded as a gap filler which is may be used to compensate some flatness defaults of the element contact surface 26 and/or some possible parallelism defects between the element contact surface 26 and the insert contact surface 16. In addition or instead of the above cited functions, the thermal interface material 30 can also play a gluing role for assembling the two aforementioned contact surfaces 16, 26. Due to its good thermal conductivity properties, the thermal interface material 30 helps to eliminate any remaining interstitial air gaps between the contact surfaces 16, 26 and helps to evacuate the heat emitted by the heating element 25. The thermal interface material 30 may typically consist of a gel, glue, a pad, an adhesive tape or thermal grease for example.

According to another implementation, the insert 15 further includes a gripping means 18 that can be used for helping the insert 15 to be adjusted within the body 11. In the examples shown in FIGS. 1 and 3-5, the gripping means 18 consists of a hole, especially a pair of holes having diametrically opposite locations with respect to the axis of rotation of the insert 15. The pair of holes allows inserting therein a tool, such as a wrench for example, which allows the insert 15 to be rotated or pushed so that it can be easily moved along its axis of movement X-X. In the implementations shown as examples in the aforementioned figures, the pair of holes consists of blind holes open on the contact surface 16 of the insert 15. In further implementations, the gripping means 18 may be arranged on the surface opposite to the insert contact surface 16. In addition, the gripping means 18 may consist of any means for gripping the insert 15 by hand or with a tool. Therefore, the gripping means 18 may also consist of a projection extending from the surface opposite to the insert contact surface 16.

As shown in the figures, the insert 15 further includes a plurality of heat exchanger elements 19 arranged on the surface opposite to the insert contact surface 16. Because the surface onto which the heat exchanger elements 19 can take place is not intended to come into contact with the element 25 to be cooled, it may also referred to as a free surface of the insert 15. The heat exchanger elements 19 may consist of a plurality of pins, plates or fins extending away from the area where the heat originates. In some implementations, the heat exchanger elements 19 extend above or beyond the body 11, as schematically shown in FIGS. 1-3 and 5, or within a cooling channel 11′ which may be part of the body, as depicted in FIG. 4.

Therefore and as shown in FIG. 4, the body 11 may further include, on a body free surface opposite to the element 25 to be cooled, at least one of a plurality of heat exchanger elements 19 and at least one cooling channel 11′ for transporting a fluid.

The fluid transported by the cooling channel 11′ may be a gas or a liquid. The gas may be air or any other cooling gas, and the liquid may typically be water, oil or any other convenient liquid. The cooling channel 11′ may be integrated within the body 11 of the heating sink 10 or may be attached to the body 11.

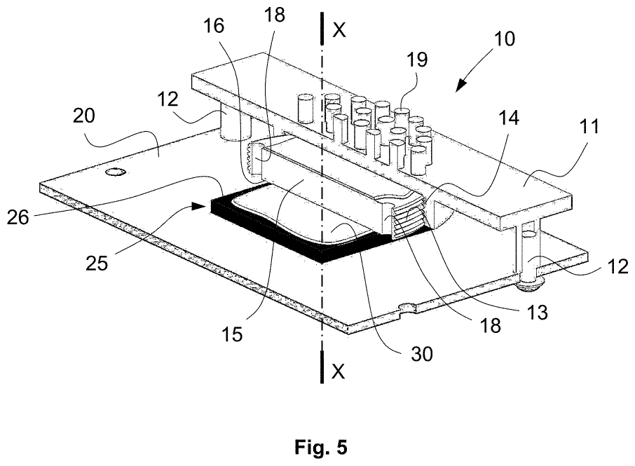

FIG. 5 illustrates another implementation of the present heat sink. As illustrated, the heat exchanger elements 19 may be part of the body 11 and may extend in a direction away from the free surface of the body 11. As shown in FIG. 5, it should be also noted that the second threaded part 14 of the body 11 may consist of a blind threaded hole arranged within the body 11. In that case and as shown in FIG. 5, a second layer of a thermal interface material 30 may take place between the insert 15 and the body 11, in particular to increase the heat transfer between the insert 15 and the bottom of the blind threaded hole of the body 11.

The heat sink 10 may be made of any suitable thermal conductive material such as aluminum, copper or a combination of any materials for example. It should be also noted that the heat sink 10 may be obtain according to any possible combination of the features or the implementations disclosed in the present description.

Simulations based on examples of the present heat sink 10 have shown that it is possible to obtain a significant temperature reduction of the element 25 to be cooled.

The present disclosure further relates to a printed circuit board as a support 20 non-adjustably mounted on a heat sink 10 according to any implementation of the heat sink 10 or according to any possible combination of its implementations.

As schematically depicted in FIG. 1, the present disclosure also relates to an ECU 40, in particular a vehicle ECU comprising a heat sink 10 according to any of its implementations or according to any possible combination of its implementations.

In addition to the above descriptions, the present disclosure further relates to a vehicle 50, in particular a motor vehicle, comprising the ECU 40 or the aforementioned printed circuit board defined as the support 20 non-adjustably mounted on a heat sink 10, according to any implementation of the heat sink 10 or according to any possible combination of its implementations.

Although an overview of the inventive subject matter has been described with reference to specific example implementations, various modifications and changes may be made to these implementations without departing from the broader spirit and scope of implementations of the disclosure disclosed in the present description.

What is claimed is:

1. A heat sink comprising:
a body configured to be non-adjustably mounted on a support having at least one element to be cooled, the body comprising:
at least one cooling channel configured to transport a fluid, the at least one cooling channel disposed on a body free surface opposite the element to be cooled; and
an insert having an insert contact surface, the insert adjustably fitted in the body such that the insert contact surface comes into contact with the element to be cooled.

2. The heat sink as described in claim 1, wherein the insert is adjustable along an axis of movement (X-X) that is perpendicular to an element contact surface of the element to be cooled.

3. The heat sink as described in claim 1, wherein the insert is adjustably fitted into the body via a first threaded part of the insert which engages a second threaded part of the body.

4. The heat sink as described in claim 3, wherein the first threaded part of the insert which engages the second threaded part of the body is sufficient to provide a sealing.

5. The heat sink as described in claim 3, wherein the first threaded part is located at a periphery of the insert and the second threaded part is a threaded hole arranged within the body.

6. The heat sink as described in claim 1, wherein the insert is adjustably fitted into the body via a push-fit inter-engagement.

7. The heat sink as described in claim 6, wherein the push-fit inter-engagement between the body and the insert involves a periphery of the insert in its entirety.

8. The heat sink as described in claim 1, further comprising a sealing between the insert and the body.

9. The heat sink as described in claim 8, wherein:
the insert is adjustably fitted into the body via a first threaded part of the insert which engages a second threaded part of the body; and
the sealing is at least one of a thread sealant or a thread lock.

10. The heat sink as described in claim 8, wherein the sealing is an O-ring, wherein the O-ring protrudes at a periphery of the insert.

11. The heat sink as described in claim 1, wherein the insert is adjustably fitted into the body to contact the element to be cooled via a first layer of a thermal interface material.

12. The heat sink as described in claim 1, wherein the insert further comprises a gripping means for helping the insert to be adjusted within the body.

13. The heat sink as described in claim 12, wherein the insert further comprises a plurality of heat exchanger elements arranged on a free surface opposite to the insert contact surface.

14. The heat sink as described in claim 13, wherein the body further comprises, on a body free surface opposite to the element to be cooled, a plurality of heat exchanger elements.

15. The heat sink as described in claim 1, wherein the insert further comprises a plurality of heat exchanger elements arranged on a free surface opposite to the insert contact surface.

16. The heat sink as described in claim 1, wherein the body further comprises, on a body free surface opposite to the element to be cooled, a plurality of heat exchanger elements.

17. The heat sink as described in claim 1, wherein the support comprises a printed circuit board.

18. The heat sink as described in claim 1, wherein the heat sink is integrated in an automobile.

19. The heat sink as described in claim 18, wherein the support comprises a printed circuit board of an electronic control unit.

20. The heat sink as described in claim 19, wherein the heat sink is configured to cool at least one element of the printed circuit board and secure the printed circuit board within the electronic control unit.
